(19) United States
(12) Patent Application Publication
(10) Pub. No.: US 2025/0316510 A1
(43) Pub. Date: Oct. 9, 2025

(54) SUBSTRATE LOADING UNIT AND METHOD OF MANUFACTURING DISPLAY DEVICE BY USING THE SAME

(71) Applicant: Samsung Display Co., LTD., Yongin-si, Gyeonggi-do (KR)

(72) Inventor: MINJONG CHEON, Yongin-si (KR)

(21) Appl. No.: 19/031,583

(22) Filed: Jan. 18, 2025

(30) Foreign Application Priority Data
Apr. 4, 2024 (KR) 10-2024-0045934

(51) Int. Cl. H01L 21/673; C03C 15/00

(52) U.S. Cl. CPC H01L 21/6734; C03C 15/00

(57) ABSTRACT

A substrate loading unit includes: a first frame; a second frame spaced apart from the first frame in a first direction; and fixed parts disposed between the first frame and the second frame, and spaced apart from each other in a second direction. The fixed parts include: support bars extending in the first direction, and a plurality of support parts disposed on side surfaces of the first support bars, the side surfaces facing each other. A state, in which the support parts extend in a third direction is defined as a first state, and a state, in which the support parts extend in the first direction, is defined as a second state, and a distance between support parts adjacent to each other in the first direction among the plurality of support parts varies when the plurality of support parts is changed from the first state to the second state.

This application claims priority to Korean Patent Application No. 10-2024-0045934, filed on Apr. 4, 2024, and all the benefits accruing therefrom under 35 U.S.C. § 119, the content of which in its entirety is herein incorporated by reference.

### BACKGROUND

Embodiments of the present disclosure described herein relate to a substrate loading unit, and a method of manufacturing a display device by using the same.

A display device is a device that provides images to the user, and is used in various multimedia devices, such as televisions, mobile phones, tablet computers, and game consoles. A display device includes various modules to display images. Furthermore, the display device includes a window for protecting the modules of the display device.

Meanwhile, the window may be prevented from being easily damaged by an external impact through a strengthening process. The strengthening process may be performed after the window is loaded on the substrate loading unit.

### SUMMARY

Embodiments of the present disclosure provide a substrate loading unit that prevents a window from being damaged when the window is loaded on the substrate loading unit and a process of strengthening the window is performed, and a method of manufacturing a display device by using the same.

According to an embodiment, a substrate loading unit includes: a first frame, a second frame spaced apart from the first frame in a first direction, and a plurality of fixed parts disposed between the first frame and the second frame, and spaced apart from each other in a second direction crossing the first direction, the fixed parts include a plurality of first support bars extending in the first direction, and a plurality of support parts disposed on side surfaces of the first support bars, the side surfaces facing each other, a state, in which the plurality of support parts extend in a third direction crossing a plane defined by the first direction and the second direction, is defined as a first state, and a state, in which the plurality of support parts extend in the first direction, is defined as a second state, and a distance between support parts adjacent to each other in the first direction among the plurality of support parts varies when the plurality of support parts is changed from the first state to the second state.

According to an embodiment, a method of manufacturing a display device includes: cutting a mother substrate and providing a preliminary substrate; loading the preliminary substrate on a first substrate loading unit and etching the preliminary substrate; after the etching of the preliminary substrate, loading the preliminary substrate on a second substrate loading unit and strengthening the preliminary substrate; after the strengthening of the preliminary substrate, loading the preliminary substrate on a third substrate loading unit and etching the preliminary substrate, and combining a substrate manufactured through the etching to a display module. Each of the first substrate loading unit, the second substrate loading unit, and the third substrate loading unit includes: a plurality of first support bars extending in the first direction, and disposed on opposite sides of the preliminary substrate, which are opposite to each other in a second direction crossing the first direction, and a plurality of first support parts disposed on side surfaces of the first support bars, which are defined as surfaces that face each other, and the plurality of support parts are configured to rotate about a rotation axis being parallel to the second direction.

### BRIEF DESCRIPTION OF THE FIGURES

The above and other aspects and features of the present disclosure will become apparent by describing in detail embodiments thereof with reference to the accompanying drawings.

FIGS. 1A and 1B are a substrate loading unit according to an embodiment of the present disclosure.

FIGS. 2A and 2B illustrate the substrate loading unit illustrated in FIG. 1.

FIGS. 3A and 3B are perspective views of a substrate loading unit according to an embodiment of the present disclosure.

FIGS. 4A and 4B are perspective views of a substrate loading unit according to an embodiment of the present disclosure.

FIG. 5A is a perspective view illustrating an electronic device manufactured by using a substrate loading unit.

FIG. 5B is a view illustrating a folding state of the electronic device illustrated in FIG. 5A.

FIG. 6 is an exploded perspective view of the electronic device illustrated in FIG. 5A.

FIG. 7 is a cross-sectional view of a display device illustrated in FIG. 6.

FIG. 8 is a flowchart illustrating a method of manufacturing a window illustrated in FIG. 6.

FIG. 9 is a perspective view of a mother substrate for describing a cutting process.

FIGS. 10A and 10B are perspective views for describing loading of a preliminary substrate.

FIGS. 11A to 11C are cross-sectional views viewed in a second direction to describe a process of strengthening a preliminary substrate.

FIGS. 12A and 12B are cross-sectional views for describing an operation of combining a window with a display module.

### DETAILED DESCRIPTION

In the specification, when it is mentioned that a component (or an area, a layer, a part, or the like) is “disposed on”, “connected to”, or “coupled to” another component, it means that the former component may be directly disposed on, connected to, or coupled to the latter component or a third component may be disposed between the components. The expression of “directly disposed” may mean that none of a layer, a film, an area, and a plate is added between a part, such as the layer, the film, the area, and the plate, and another part. For example, the expression of “directly disposed” may mean that the two layers or two members are disposed while an additional member, such as an adhesive member, is not used therebetween.

The same reference numerals denote the same components. Furthermore, in the drawings, thicknesses, ratios, dimensions of the components are exaggerated for an effective description of the technical contents. The term “and/or” includes one or more combinations that may be defined by the associated components.

Furthermore, in describing the various components, the terms, such as “first” and “second” may be used, but the present disclosure is not limited by the terms. The terms are simply for distinguishing the components. For example, a first component may be named a second component, and similarly the second component also may be named the first component while not departing from the scope of the present disclosure. A singular expression includes a plural expression unless an exemption is explicitly described in the context.

Furthermore, the terms, such as “under”, “below”, “on”, and “above”, are used to describe an associative relationship between the components illustrated in the drawings. The terms are relative concepts, and are described with respect to directions indicated in the drawings.

Unless otherwise defined, all terms, including technical and scientific terms, used herein have the same meaning as commonly understood by those skilled in the art to which the present disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, embodiments of the present disclosure will be described with reference to the drawings.

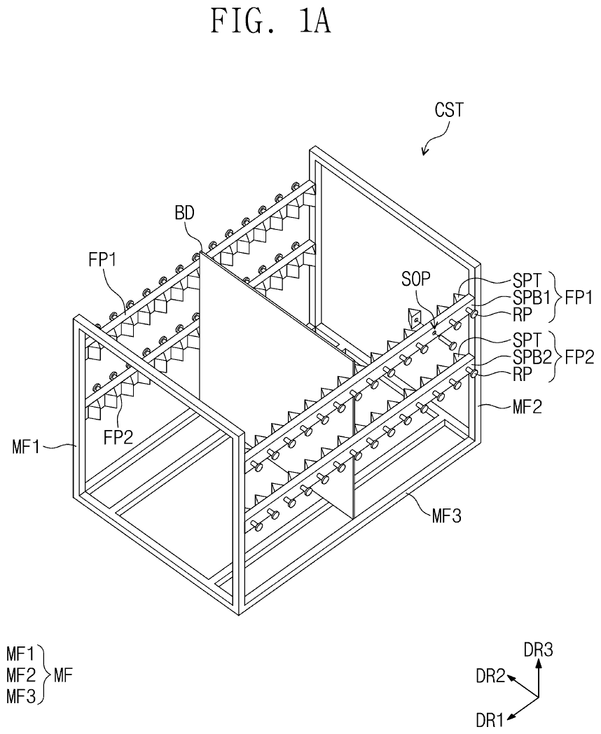

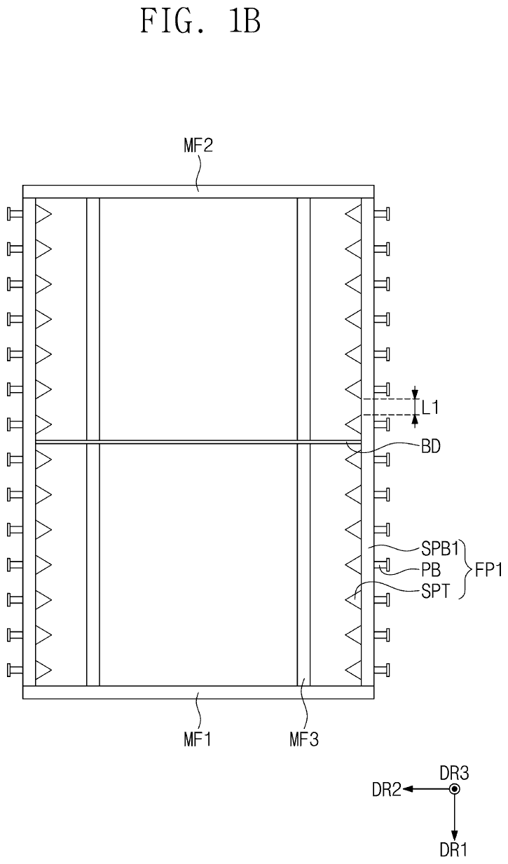

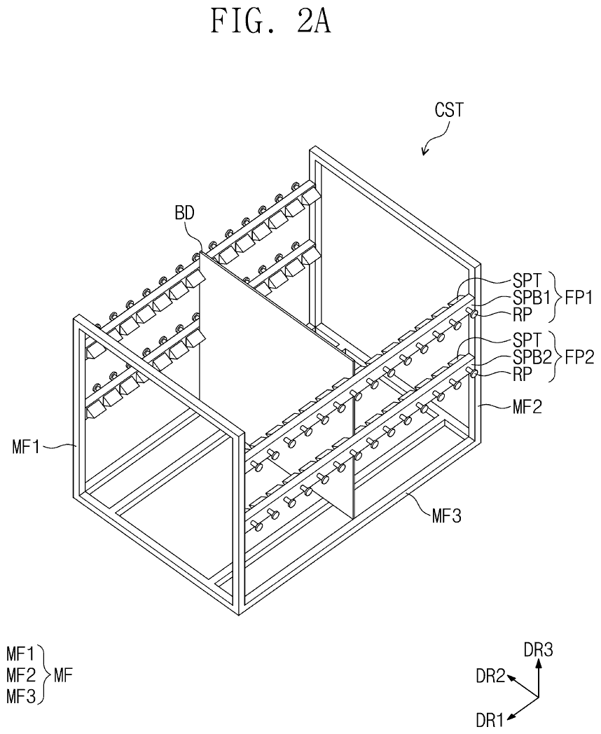

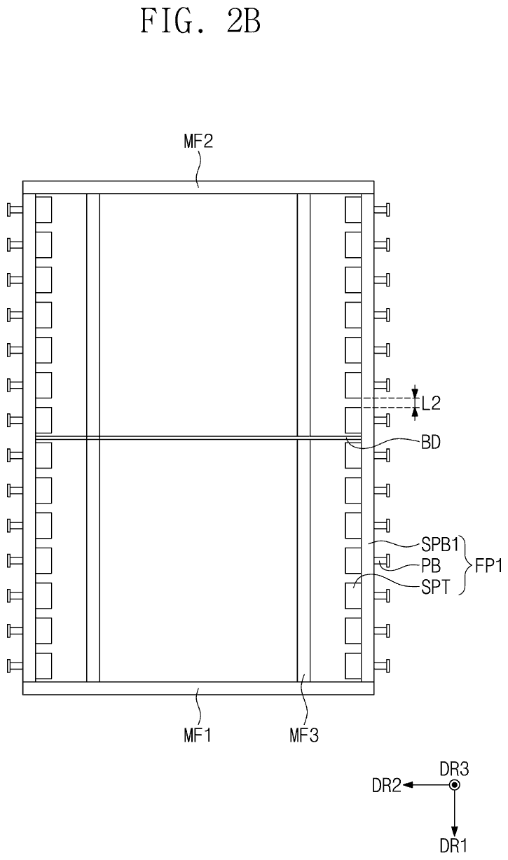

FIGS. 1A and 1B are a substrate loading unit according to an embodiment of the present disclosure. FIGS. 2A and 2B illustrate the substrate loading unit illustrated in FIG. 1.

By way of example, FIGS. 1A and 2A are perspective views, and FIGS. 1B and 2B are plan views.

Referring to FIG. 1A, a substrate loading unit CST may include a main frame MF and fixed parts FP1 and PF2. The main frame MF may include a first frame MF1, a second frame MF2, and a plurality of lower frames MF3.

The first frame MF1 and the second frame MF2 may be arranged in a first direction DR1. The lower frames MF3 may be disposed between the first frame MF1 and the second frame MF2. The lower frames MF3 may be disposed on a lower side of the first frame MF1 and the second frame MF2. Substantially, the first frame MF1, the second frame MF2, and the lower frames MF3 may be formed integrally.

The lower frames MF3 may extend in the first direction DR1, and may be arranged in a second direction DR2 that crosses the first direction DR1. The lower frame MF3 may extend from the first frame MF1 toward the second frame MF2. The lower frame MF3 may be connected to the first frame MF1 and the second frame MF2.

Hereinafter, a direction that substantially perpendicularly crosses a plane defined by the first and second directions DR1 and DR2 is defined as a third direction DR3. Furthermore, in the specification, “when viewed on a plane” may be defined as being viewed in the third direction DR3, and the same meaning with “in a plan view”.

The first frame MF1 may have a rectangular frame shape that is parallel to a plane defined by the first direction DR1 and the third direction DR3. The second frame MF2 may be spaced apart from the first frame MF1 in the first direction DR1. The second frame MF2 may have a rectangular frame shape that is parallel to a plane defined by the first direction DR1 and the third direction DR3.

The fixed parts FP1 and FP2 may be disposed between the first frame MF1 and the second frame MF2. The fixed parts FP1 and FP2 may be placed on the lower frame MF3.

The fixed parts FP1 and FP2 may include first fixed parts FP1 and second fixed parts FP2. The first fixed parts FP1 may be arranged in the second direction DR2 between the first frame MF1 and the second frame MF2. The second fixed parts FP2 may be arranged in the second direction DR2 between the first frame MF1 and the second frame MF2. The first fixed parts FP1 and the second fixed parts FP2 may be arranged in the third direction DR3. The first fixed parts FP1 may be disposed on the second fixed parts FP2.

The first fixed parts FP1 may include a plurality of first support bars SPB1, a plurality of support parts SPT, and a plurality of rotation pins RP. The first support bars SPB1 may extend in the first direction DR1 and be arranged in the second direction DR2. The first support bars SPB1 may extend from the first frame MF1 to the second frame MF2 in the first direction DR1. Each of the first support bars SPB1 may include opposite sides, which are opposite to each other in the first direction DR1 and coupled to the first frame MF1 and the second frame MF2.

The support parts SPT may be disposed on ones of the opposite side surfaces of the first support bars SPB1, which are opposite to each other in the second direction DR2. The support parts SPT may be arranged in the first direction DR1 on side surfaces of the first support bars SPB1. Among the opposite side surfaces of the first support bars SPB1, which are opposite to each other in the second direction DR2, side surfaces thereof may be defined as side surfaces that face each other.

The support parts SPT may face each other in the second direction DR2. The support parts SPT of any one of the two first fixed parts FP1 may be arranged to correspond to the support parts SPT of the other first fixed parts FP1.

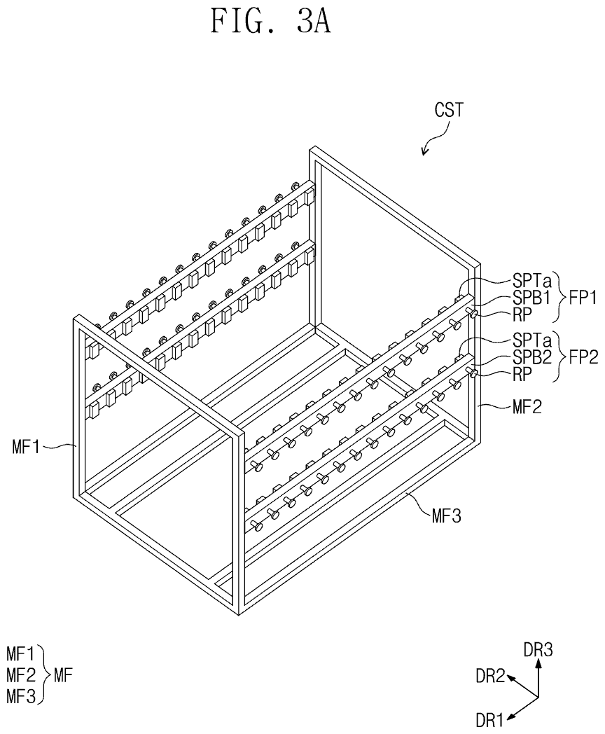

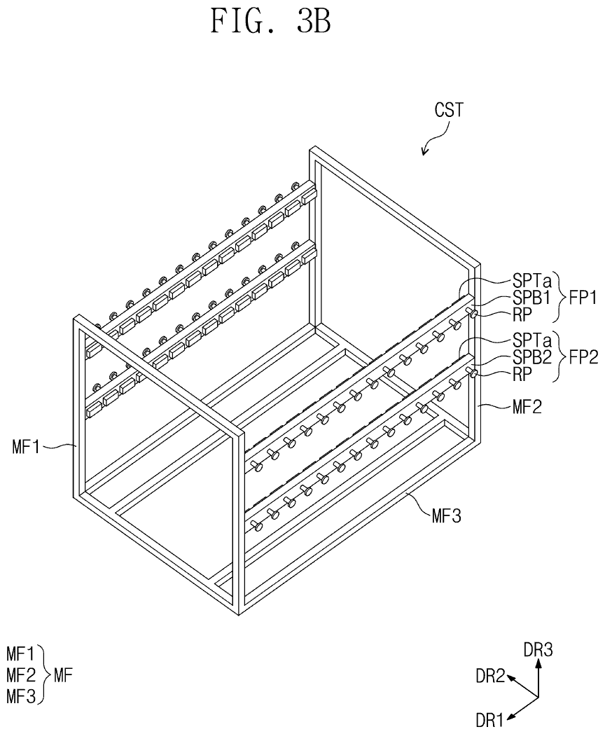

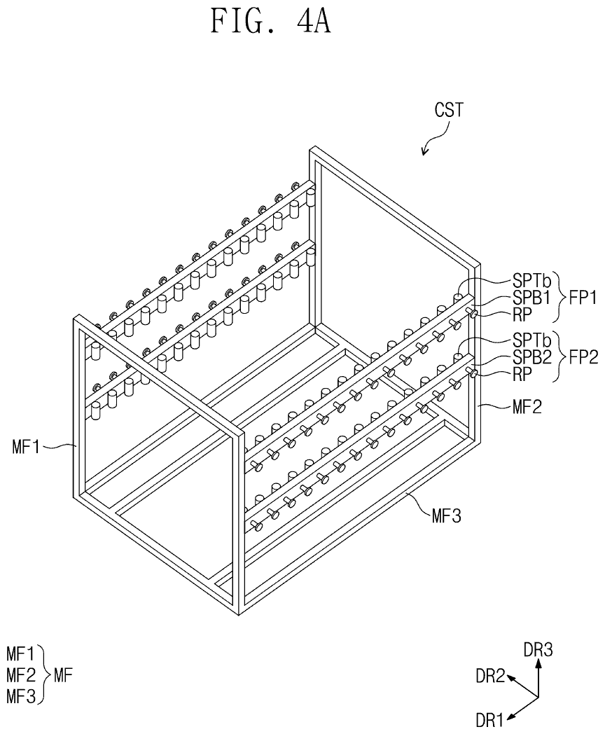

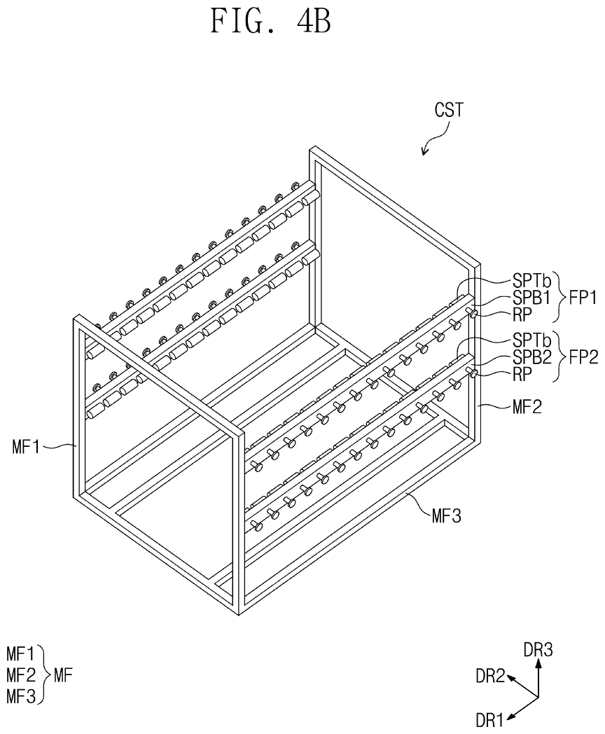

The support parts SPT may extend in the third direction DR3. The support parts SPT may have a polygonal column shape. By way of example, the support parts SPT may have a triangular prism shape. However, the present disclosure is not limited thereto, and the support parts SPT may have various shapes. The shape of the support parts SPT will be described in detail in FIGS. 3A to 4B.

The rotation pins RP may be inserted into insertion openings SOP that are defined in the first support bars SPB1. The rotation pins RP may be rotated about a rotation axis that is parallel to the second direction DR2 in the insertion openings SOP. The rotation pins RP may pass through the first support bars SPB1 and be coupled to the support parts SPT. The rotation pins RP may be coupled to the support parts SPT through the insertion openings SOP.

As illustrated in FIGS. 1A and 1B, a state, in which the support parts SPT extend in the third direction DR3, may be defined as a first state. As illustrated in FIGS. 2A and 2B, a state, in which the support parts SPT extend in the first direction DR1, may be defined as a second state.

By a user or a motor, the rotation pins RP may be rotated about the rotation axis that is parallel to the second direction DR2. When the rotation pins RP is rotated, the support parts SPT connected to the rotation pins RP may be rotated about the rotation axis parallel to the second direction DR2. Accordingly, the support parts SPT may be changed from the first state to the second state or from the second state to the first state.

When viewed on a plane, a length of the support parts SPT in the first direction DR1 in the first state may be smaller than a length of the support parts SPT in the first direction DR1 in the second state. When the first state is changed to the second state, a distance between support parts SPT that are adjacent to each other in the first direction DR1 may vary.

In detail, a minimum distance between support parts SPT that are adjacent to each other in the first direction DR1 in the first state may be defined as a first distance L1. A minimum distance between support parts SPT that are adjacent to each other in the first direction DR1 in the second state may be defined as a second distance L2. The first distance L1 may be greater than the second distance L2. As used herein, the minimum distance is a distance between adjacent ends of adjacent support parts SPT in the first direction DR1.

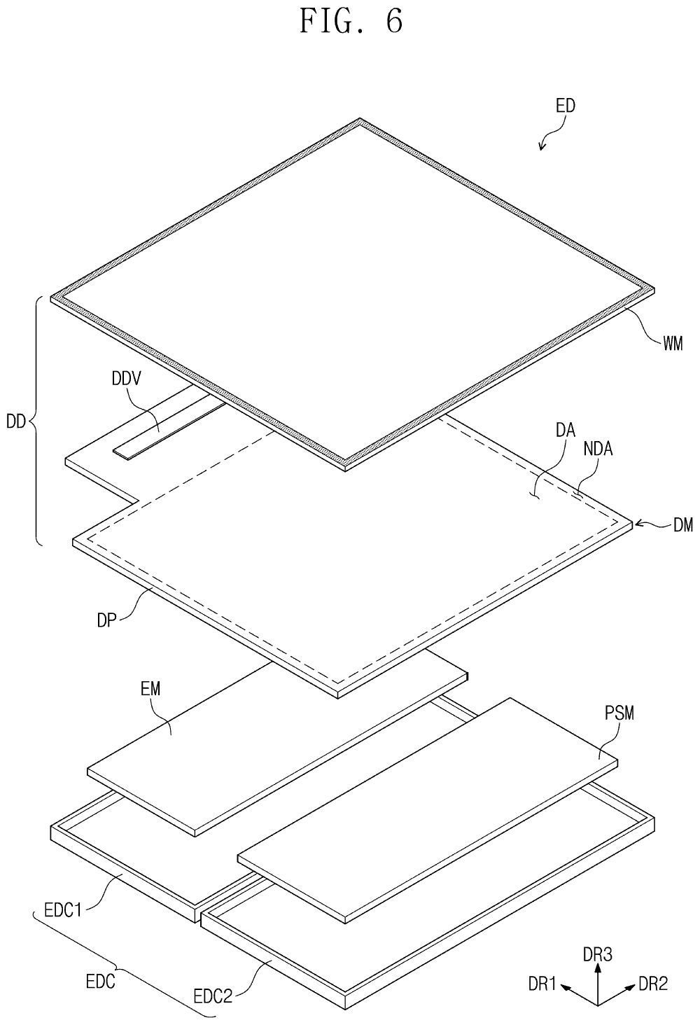

A substrate BD may be loaded on the substrate loading unit CST. By way of example, the substrate BD may be the same as a window WM in FIG. 6. Hereinafter, the substrate BD will be described as the window WM. The window WM may be loaded between support parts SPT that are adjacent to each other in the first direction DR1.

When the window WM is loaded on the substrate loading unit CST, a danger of corners of the window WM colliding with the support parts SPT may increase as the distance between support parts SPT that are adjacent to each other in the first direction DR1 becomes smaller. Accordingly, the corners of the window WM may be damaged, a defect may be caused in a display device DD (see FIG. 6).

Furthermore, when the distance between the support parts SPT that are adjacent to each other in the first direction DR1 increases, curving or shaking of the window WM may increase between the support parts SPT during a process of strengthening the window WM, and thus, a defect may be caused in the strengthening process.

However, in an embodiment of the present disclosure, when the window WM (see FIG. 6) is loaded on the substrate loading unit CST, the support parts SPT may be in the first state. The distance between support parts SPT that are adjacent to each other in the first direction DR1 may be relatively increased. Accordingly, when the window WM is loaded between the support parts SPT, a danger of the window WM colliding with the support parts SPT may be effectively decreased. Accordingly, the window WM may not be damaged and the display device DD (see FIG. 6) may not have a defect.

Furthermore, after the window WM is inserted, the support parts SPT may be rotated. As the support parts SPT are rotated, the distance between the support parts SPT adjacent to each other in the first direction DR1 may vary. The distance between the support parts SPT that are adjacent to each other in the first direction DR1 may be decreased. Accordingly, during the process of strengthening the window WM, curving or shaking of the window WM between the support parts SPT is decreased, and a defect in the strengthening process may be effectively prevented.

Referring to FIG. 1A, the second fixed parts FP2 may be disposed on a lower side of the first fixed parts FP1. The second fixed parts FP2 may include a second support bar SPB2, a plurality of support parts SPT, and a plurality of rotation pins RP. Because the second fixed parts FP2 have substantially the same structure as a structure of the first fixed parts FP1, a description of the second fixed parts FP2 will be omitted.

FIGS. 3A and 3B are perspective views of a substrate loading unit according to an embodiment of the present disclosure.

By way of example, support parts SPTa of FIG. 3A are in the first state, and the support parts SPTa of FIG. 3B are in the second state.

A description of, among the components illustrated in FIGS. 3A and 3B, components that are the same as those described with reference to the drawings described above will be omitted or briefly made.

Referring to FIGS. 3A and 3B, the support parts SPTa may have a hexahedral shape. When the support parts SPTa are in the first state, the support parts SPTa may extend in the third direction DR3. When the support parts SPTa are in the second state, the support parts SPTa may extend in the first direction DR1.

When the support parts SPTa are changed from the first state to the second state, the distance between the support parts SPTa that are adjacent to each other in the first direction DR1 may be decreased. A change in the distance between support parts SPTa that are adjacent to each other in the first direction DR1 has been described in FIGS. 1B and 2B, and this may be equally applied to FIGS. 3A and 3B.

FIGS. 4A and 4B are perspective views of a substrate loading unit according to an embodiment of the present disclosure.

By way of example, the support parts SPTb of FIG. 4A are in the first state, and the support parts SPTb of FIG. 4B are in the second state.

A description of, among the components illustrated in FIGS. 4A and 4B, components that are the same as those described with reference to the drawings described above will be omitted or briefly made.

Referring to FIGS. 4A and 4B, the support parts SPTb may have a cylindrical shape. When the support parts SPTb are in the first state, the support parts SPTb may extend in the third direction DR3. When the support parts SPTb are in the second state, the support parts SPTb may extend in the first direction DR1.

When the support parts SPTb are changed from the first state to the second state, the distance between the support parts SPTb that is adjacent to each other in the first direction DR1 may be decreased. A change in the distance between support parts SPTb that are adjacent to each other in the first direction DR1 has been described in FIGS. 1B and 2B, and this may be equally applied to FIGS. 4A and 4B.

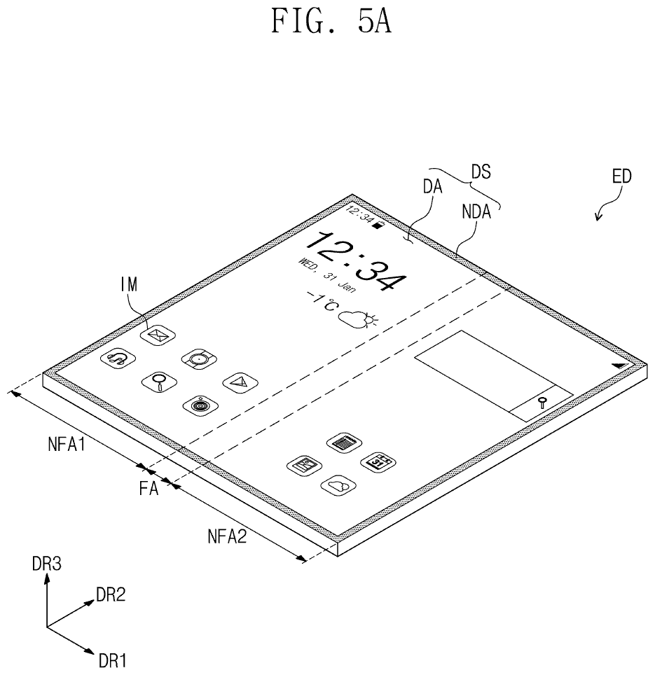

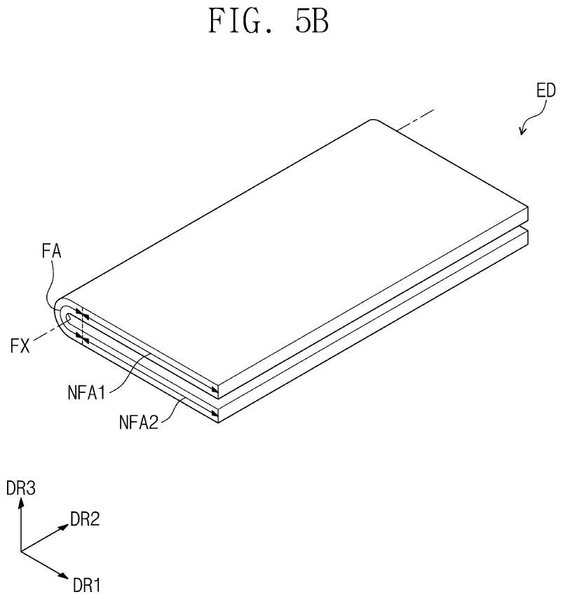

FIG. 5A is a perspective view illustrating an electronic device manufactured by using a substrate loading unit. FIG. 5B is a view illustrating a folding state of the electronic device illustrated in FIG. 5A.

Referring to FIG. 5A, an electronic device ED according to an embodiment of the present disclosure may have a rectangular shape having short sides that extend in the first direction DR1 and long sides that extend in the second direction DR2. However, the present disclosure is not limited thereto, and the electronic device ED may have various shapes, such as a circular shape and a polygonal shape. The electronic device ED may be flexible

The electronic device ED may include a folding area FA and a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2. The folding area FA, the first non-folding area NFA1, and the second non-folding area NFA2 may be arranged in the first direction DR1.

As an example, one folding area FA and two non-folding areas NFA1 and NFA2 are illustrated, but the numbers of folding areas FA and non-folding areas NFA1 and NFA2 are not limited thereto. For example, the electronic device ED may include more than two non-folding areas, and a plurality of folding areas disposed between the non-folding areas in another embodiment.

An upper surface of the electronic device ED may be defined as a display surface DS, and the display surface DS may have a plane that is defined by the first direction DR1 and the second direction DR2. Images IM that are created by the electronic device ED may be provided to the user through the display surface DS.

The display surface DS may include a display area DA and a non-display area NDA that surrounds the display area DA. The display area DA may display an image, and the non-display area NDA may not display an image. The non-display area NDA may define a periphery of the electronic device ED, which surrounds the display area DA and is printed in a specific color.

Referring to FIG. 5B, the electronic device ED may be a foldable electronic device ED that is folded or unfolded. For example, the folding area FA may be curved with respect to a folding axis FX that is parallel to the second direction DR2 so that the electronic device ED may be folded. The folding axis FX may be defined as a long axis that is parallel to the long sides of the electronic device ED. When the electronic device ED is folded, the first non-folding area NFA1 and the second non-folding area NFA2 may face each other, and the electronic device ED may be in-folded to prevent the display surface DS from being exposed to an outside. However, the embodiments of the present disclosure are not limited thereto. For another example, the electronic device ED may be out-folded so that the display surface DS is exposed to the outside with respect to the folding axis FX. Furthermore, although not illustrated, the electronic device ED may be in-folded and out-folded at the same time.

FIG. 6 is an exploded perspective view of the electronic device illustrated in FIG. 5A.

Referring to FIG. 6, the electronic device ED may include a display device DD, an electronic module EM, a power supply module PSM, and a case EDC. Although not illustrated, the electronic device ED may further include a mechanical structure (e.g., a hinge) for controlling a folding operation of the display device DD.

The display device DD may create images and sense an external input. The display device DD may include the window WM and a display module DM. The window WM may provide a front surface of the electronic device ED. The window WM may be disposed on the display module DM to protect the display module DM. The window WM may transmit light generated in the display module DM and provide it to the user.

The display module DM may include a display panel DP. Although only the display panel DP in the stack structure of the display module DM is illustrated in FIG. 6, the display module DM may further include a plurality of components that are disposed on an upper side and a lower side of the display panel DP. The display panel DP may include a display area DA and a non-display area NDA corresponding to the display area DA and non-display area NDA of the electronic device ED of FIG. 5A.

The display module DM may include a data driving part DDV that is disposed on the non-display area NDA of the display panel DP. The data driving part DDV may be manufactured in the form of an integrated circuit chip, and may be mounted on the non-display area NDA. However, the data driving part DDV is not limited thereto, and may be mounted on a flexible circuit board that is connected to the display panel DP in another embodiment.

The electronic module EM and the power supply module PSM may be disposed on a lower side of the display device DD. Although not illustrated, the electronic module EM and the power supply module PSM may be connected to each other through a separate flexible circuit board. The electronic module EM may control an operation of the display device DD. The power supply module PSM may supply electric power to the electronic module EM.

The case EDC may accommodate the display device DD, the electronic module EM, and the power supply module PSM. The case EDC may include two first and second cases EDC1 and EDC2 to fold the display device DD. The first and second cases EDC1 and EDC2 may extend in the second direction DR2 and be arranged in the first direction DR1.

Although not illustrated, the electronic device ED may further include a hinge structure for connecting the first and second cases EDC1 and EDC2. The case EDC may be coupled to the window WM. The case EDC may protect the display device DD, the electronic module EM, and the power supply module PSM.

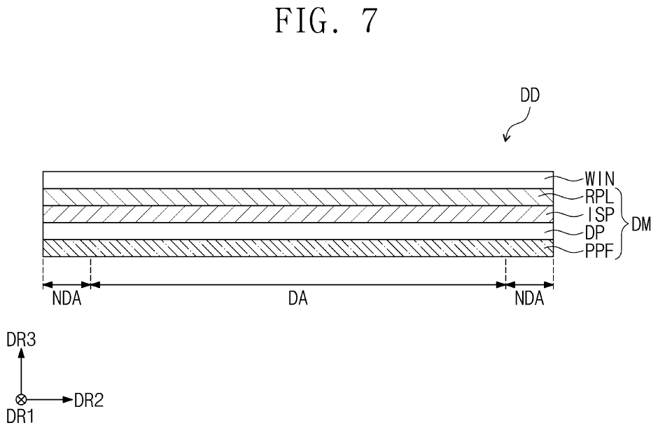

FIG. 7 is a cross-sectional view of a display device illustrated in FIG. 6.

Referring to FIG. 7, the display device DD may include the window WM and the display module DM. The display module DM may include a display panel DP, an input sensing part ISP, a reflection preventing layer RPL, and a panel protecting film PPF.

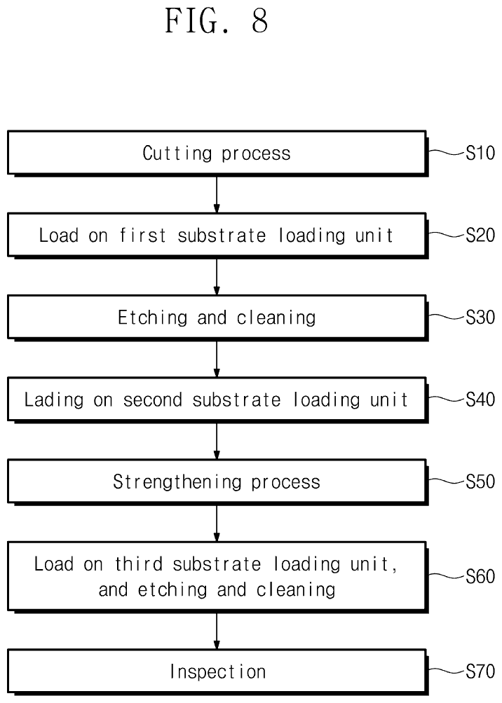

The window WM may be loaded on a substrate loading unit CSP illustrated in FIG. 1A. A plurality of windows WM may be loaded on the substrate loading unit CSP illustrated in FIG. 1A. When the display device DD is manufactured, the windows WM may be loaded on the substrate loading unit CSP, and may be fed or strengthened. The loading and strengthening of the windows WM will be described in detail in FIGS. 8 to 12B.

The display panel DP may be a flexible display panel. The display panel DP according to an embodiment of the present disclosure may be a light emitting display panel, and is not particularly limited. For example, the display panel DP may be an organic light emitting display panel or an inorganic light emitting display panel. A light emitting layer of the organic light emitting display panel may include an organic light emitting material. The light emitting layer of the inorganic light emitting display panel may include quantum dots and quantum rods.

The input sensing part ISP may be disposed on the display panel DP. The input sensing part ISP may include a plurality of sensing units (not illustrated) for sensing an external input in a capacitive scheme. The input sensing part ISP may be manufactured directly on the display panel DP when the display device DD is manufactured. However, the present disclosure is not limited thereto, and the input sensing part ISP may be manufactured as a panel that is separate from the display panel DP, and may be attached to the display panel DP through an adhesion layer in another embodiment.

The reflection preventing layer RPL may be disposed on the input sensing part ISP. The reflection preventing layer RPL may be manufactured directly on the input sensing part ISP when the display device DD is manufactured. However, the present disclosure is not limited thereto, and the reflection preventing layer RPL may be manufactured as a separate panel, and may be attached to the input sensing part ISP by an adhesion layer in another embodiment.

The reflection preventing layer RPL may be defined as an external light reflection preventing film. The reflection preventing layer RPL may decrease a reflectance of an external light that is input from an upper side of the display device DD toward the display panel DP. The external light may not be visible to the user due to the reflection preventing layer RPL.

When external light that travels toward the display panel DP is reflected by the display panel DP and is provided to the external user again, the user may perceive the external light like a mirror. To prevent this phenomenon, by way of example, the reflection preventing layer RPL may include a plurality of color filters that display the same color as the colors of the pixels of the display panel DP.

The color filters may filter the external light in the same color as the colors of the pixels. In this case, the external light may not be visible to the user. However, the present disclosure is not limited thereto, and the reflection preventing layer RPL may include a phase retarder and/or a polarizer to reduce the reflectance of the external light in another embodiment.

The window WM may be disposed on the reflection preventing layer RPL. The window WM may protect the display panel DP, the input sensing part ISP, and the reflection preventing layer RPL from external scratches and impacts.

The panel protecting film PPF may be disposed on a lower side of the display panel DP. The panel protecting film PPF may protect a lower side of the display panel DP. The panel protecting film PPF may include a flexible plastic material, such as polyethylene terephthalate (“PET”).

Although not illustrated, the adhesion layer may be disposed between the display panel DP and the panel protecting film PPF, and the display panel DP and the panel protecting film PPF may be combined with each other by the adhesion layer. Although not illustrated, the adhesion layer may be disposed between the window WM and the reflection preventing layer RPL, and the window WM and the reflection preventing layer RPL may be combined with each other by the adhesion layer.

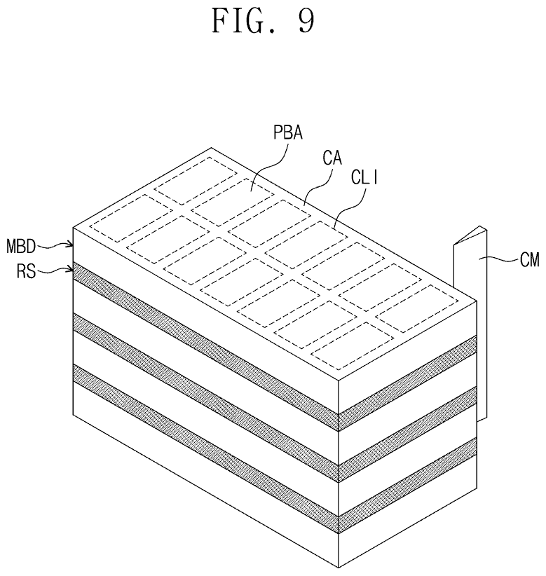

FIG. 8 is a flowchart illustrating a method of manufacturing a window illustrated in FIG. 6. FIG. 9 is a perspective view of a mother substrate for describing a cutting process.

Referring to FIGS. 8 and 9, a preliminary substrate PBD may be provided through a cutting process (S10). The cutting process (S10) may include an operation of alternately stacking mother substrates MBD and adhesion layers RS along the third direction DR3.

The mother substrates MBD may include materials having flexible properties. By way of example, the mother substrate MBD may include glass. An upper surface of the mother substrate MBD may include a substrate area PBA and a periphery area CA. A boundary between the substrate area PBA and the periphery area CA may be defined by a cutting line CLI.

The adhesion layers RS may function to fix the stacked mother substrate MBD. The adhesion layers RS may include a material having adhesive properties. For example, the adhesion layer RS may include at least one of a resin, an optically clear adhesive, rosin, and wax.

The stacked mother substrates MBD and the adhesion layers RS may be cut. The stacked mother substrates MBD and the adhesion layers RS may be cut together through a cutting member CM. For example, the mother substrates MBD and the adhesion layers RS may be cut through a computer numerical control (“CNC”).

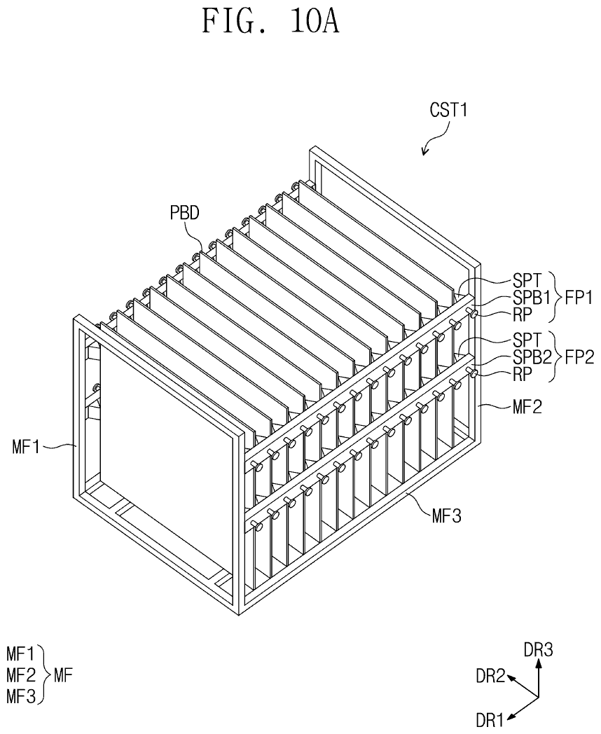

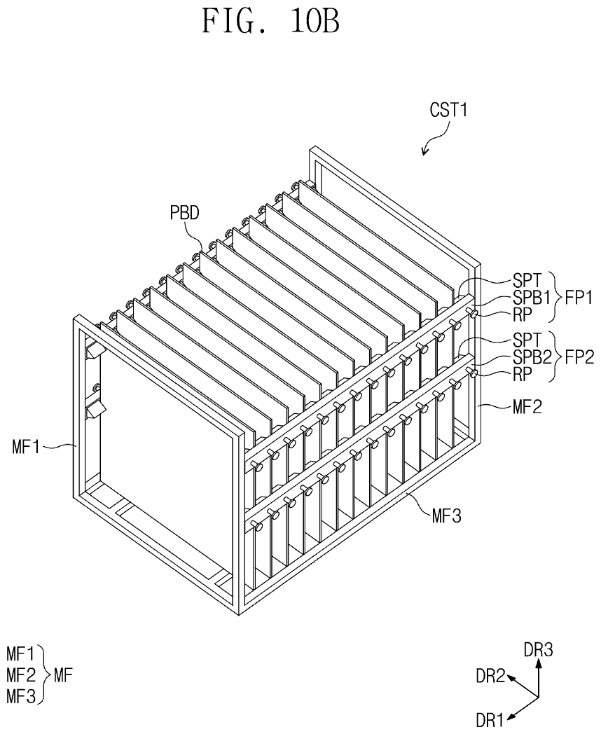

As the stacked mother substrates MBD and the adhesion layers RS are cut, the substrate area PBA may be separated from the periphery area CA. Areas of the substrate areas PBA separated from the periphery area CA may be substantially the same as an area of the window WM illustrated in FIG. 6. As the substrate areas PBA are separated from the periphery area CA, a preliminary substrate PBD (see FIG. 10A) may be provided.

FIGS. 10A and 10B are perspective views for describing loading of a preliminary substrate.

Referring to FIGS. 8 and 10A, the preliminary substrates PBA may be loaded on the first substrate loading unit CST1. The first substrate loading unit CST1 may be substantially the same as the substrate loading unit CST of FIG. 1A.

When preliminary substrates PBA are loaded on the first substrate loading unit CST1, the support parts SPT may be in the first state. As a distance between adjacent support parts SPT in the first direction DR1 relatively increases, a danger of the preliminary substrates PBA colliding with the support parts SPT may be effectively decreased.

Referring to FIGS. 8 and 10B, after the preliminary substrates PBA are loaded on the first substrate loading unit CST1, the support parts SPT may be changed to the second state. The distance between the support parts SPT that are adjacent to each other in the first direction DR1 may be decreased.

Although not illustrated, after the preliminary substrates PBA are loaded on the first substrate loading unit CST1, an etching and cleaning operation (S30) may be performed. The etching operation may be defined as an operation of processing the cut surfaces of the preliminary substrates PBA. The cleaning operation may be defined as an operation of removing residues generated during the etching operation. Then, because the support parts SPT of the first substrate loading unit CST1 are in the second state, the preliminary substrates PBA may not be curved or shaken.

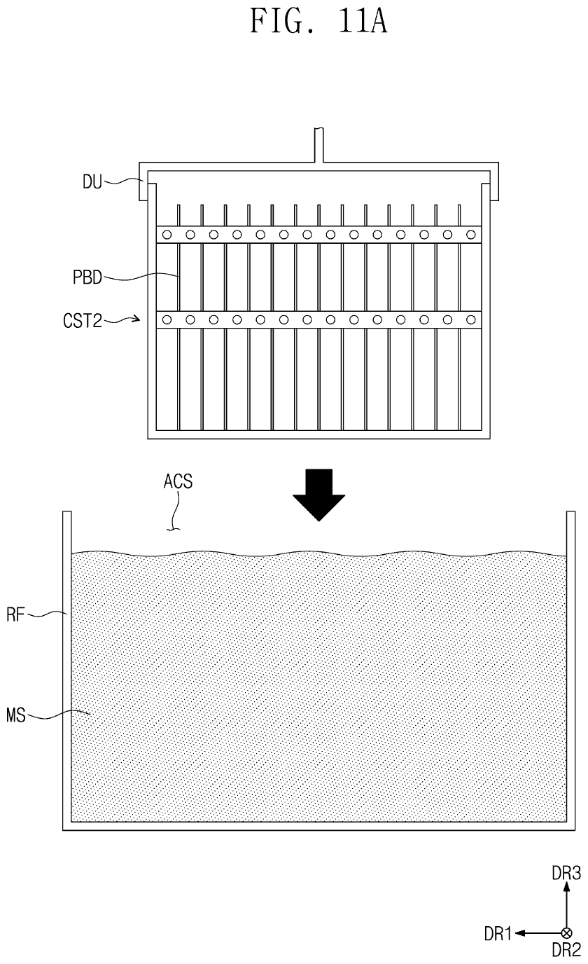

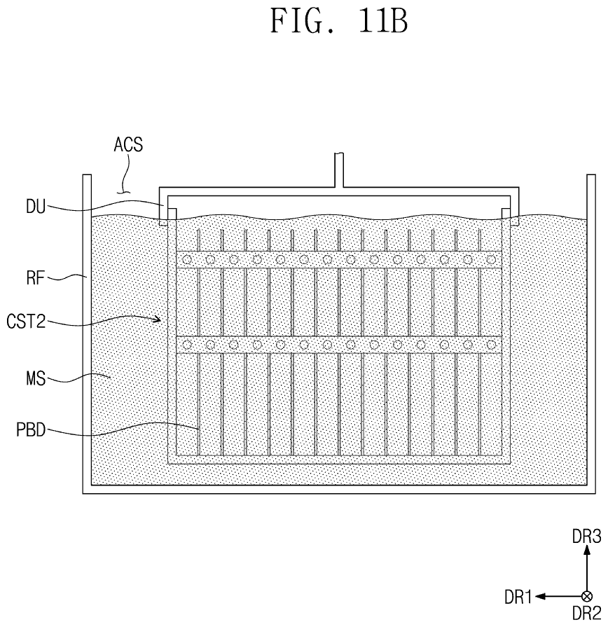

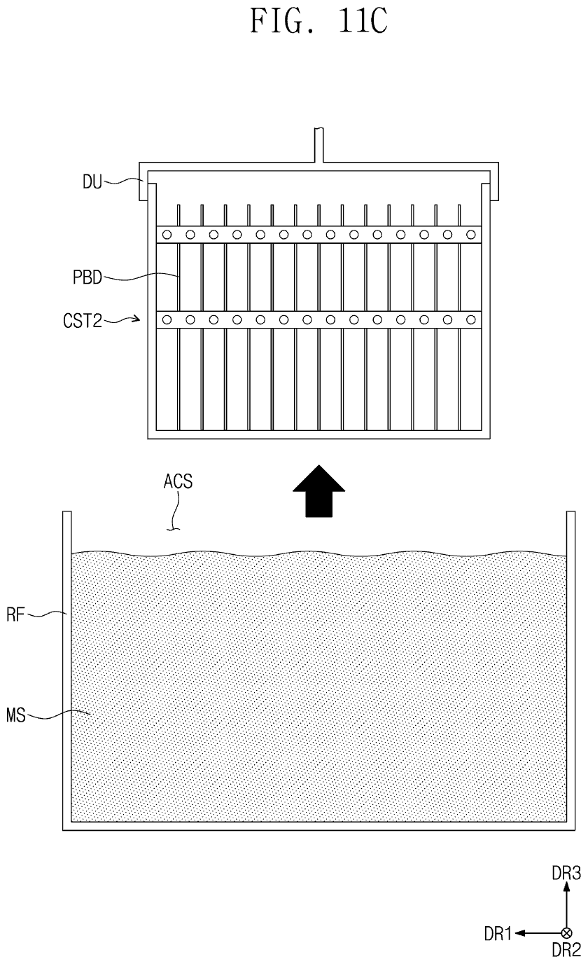

FIGS. 11A to 11C are cross-sectional views viewed in a second direction to describe a process of strengthening a preliminary substrate.

Referring to FIGS. 8 and 11A, after the etching and cleaning operation (S30) is completed, the preliminary substrates PBA may be loaded on the second substrate loading unit CST2 (S40). The second substrate loading unit CST2 may be substantially the same as the first substrate loading unit CST1 of FIG. 10A.

In FIGS. 10A and 10B, a principle of changing the support parts SPT of the first substrate loading unit CST1 from the first state to the second state has been described, and this may be equally applied to changing of the support of the second substrate loading unit CST2 from the first state to the second state.

After the preliminary substrates PBA are loaded on the second substrate loading unit CST2, a process (S50) of strengthening the preliminary substrates PBA may be performed. The strengthening process (S50) may include an operation of connecting the driving unit DU to the second substrate loading unit CST2. The second substrate loading unit CST2 connected to the driving unit DU may be moved in the third direction DR3.

A reinforcement furnace RF may be disposed on a lower side of the driving unit DU and the second substrate loading unit CST2. The reinforcement furnace RF may provide an accommodation space ACS in an interior thereof. The molten salt MS may be accommodated in the accommodation space ACS. Although not illustrated, a heating module for heating the molten salt MS may be included in the accommodation space ACS. The heating module may heat the molten salt MS.

Referring to FIG. 11B, after the molten salt MS is heated, the second substrate loading unit CST2 may be moved in the third direction DR3 by the driving unit DU and may be immersed in the molten salt MS. Then, because the support parts SPT of the second substrate loading unit CST2 are in the second state, the preliminary substrates PBA may not be curved or shaken.

The molten salt MS may strengthen the preliminary substrate PBA. By way of example, ions on the surface of the preliminary substrate PBA may be replaced with ions contained in the molten salt MS having a relatively large diameter. The surface of the preliminary substrate PBA may be strengthened by replacing ions with relatively large diameters.

Referring to FIG. 11C, the second substrate loading unit CST2 may be moved in the third direction DR3 by the driving unit DU, and may be separated from the molten salt MS.

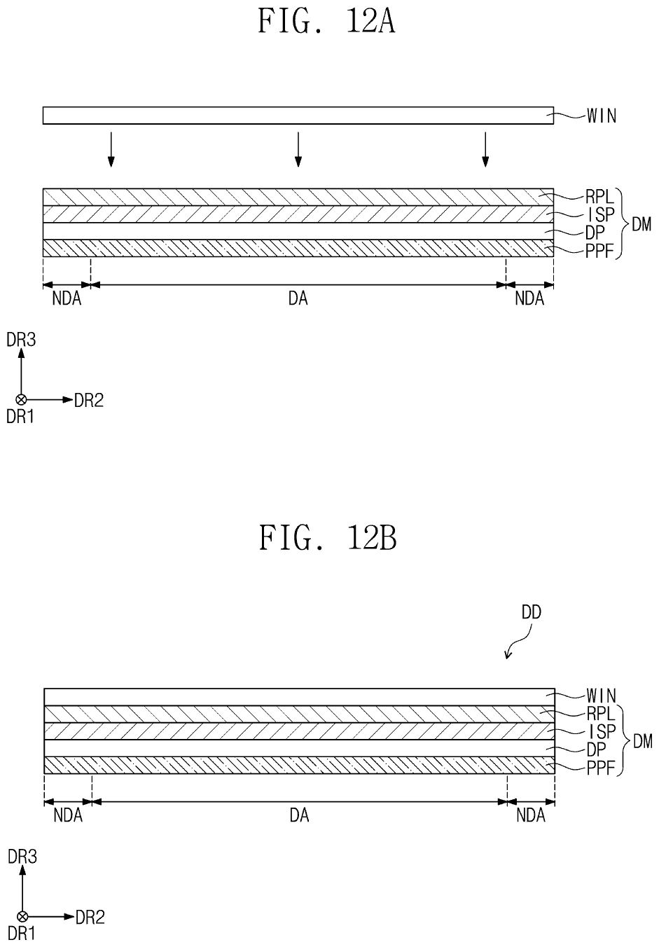

FIGS. 12A and 12B are cross-sectional views for describing an operation of combining a window with a display module.

Referring to FIG. 8, although not illustrated, after the strengthening process (S50) is completed, the etching and cleaning operation (S60) may be performed after the loading on the third substrate loading unit. The loading operation and the etching operation on the third substrate loading unit are substantially the same as the loading operation (S20) and the etching and cleaning operation (S30) on the first substrate loading unit CST1 (FIG. 10A), and a description thereof will be omitted. Because the support parts SPT of the third substrate loading unit are in the second state, the preliminary substrates PBA may not be curved or shaken. When the preliminary substrate PBA is etched and cleaned (S30), the window WM (see FIG. 6) may be manufactured.

Referring to FIGS. 8, 12A, and 12B, after the etching and cleaning operation (S60) is completed, an inspection operation (S70) may be performed. As a result of the inspection, when the window WM (see FIG. 6) meets the set quality standards, it may be combined with the display module DM. As the window WM is combined with the display module DM, a display device DD may be manufactured.

According to an embodiment of the present disclosure, when the window is loaded between the support parts that are adjacent to each other in the first direction, the distance between the support parts that are adjacent to each other in the first direction may be relatively increased. Accordingly, when the window is loaded, a possibility of the window touching the support parts may be decreased and a possibility of the window being damaged may be effectively decreased.

In addition, after the window is loaded, the support parts may be rotated around in an axis parallel to the second direction, and the distance between the support parts that are adjacent to each other in the first direction may be relatively decreased. Accordingly, it is possible to effectively prevent the window from being curved or shaken during the window strengthening process.

Although the present disclosure has been described with reference to the embodiments, it will be appreciated by an ordinary skilled in the art, to which the present disclosure pertains, that the present disclosure may be modified and changed within the scope of the appended claims without departing from the spirits and technical field of the present disclosure. Therefore, the technical scope of the present disclosure should not be limited to the detailed description of the specification, but all the technical ideas in the claims and the equivalents to the claims fall within the scope of the present disclosure.

What is claimed is:

1. A substrate loading unit comprising:
a first frame;
a second frame spaced apart from the first frame in a first direction; and
a plurality of fixed parts disposed between the first frame and the second frame, and spaced apart from each other in a second direction crossing the first direction,
wherein the fixed parts comprise:
a plurality of first support bars extending in the first direction; and
a plurality of support parts disposed on side surfaces of the first support bars, the side surfaces facing each other,
wherein a state, in which the plurality of support parts extend in a third direction crossing a plane defined by the first direction and the second direction, is defined as a first state, and a state, in which the plurality of support parts extend in the first direction, is defined as a second state, and
wherein a distance between support parts adjacent to each other in the first direction among the plurality of support parts varies when the plurality of support parts is changed from the first state to the second state.

2. The substrate loading unit of claim 1, wherein each of the plurality of support parts are rotated about a rotation axis being parallel to the second direction when the plurality of support parts is changed from the first state to the second state.

3. The substrate loading unit of claim 1, wherein the distance between the support parts adjacent to each other in the first direction in the first state is defined as a first distance,
wherein the distance between the support parts adjacent to each other in the first direction in the second state is defined as a second distance, and
wherein the first distance is greater than the second distance.

4. The substrate loading unit of claim 3, wherein substrate loading unit is configured to load a substrate between the support parts adjacent to each other in the first direction when the plurality of support parts are in the first state, and
wherein the plurality of support parts are configured to be changed into the second state after the substrate is loaded between the support parts adjacent to each other in the first direction.

5. The substrate loading unit of claim 1, wherein the fixed parts further comprise:
a plurality of rotation pins passing through the first support bars and coupled to the plurality of support parts, respectively, and
wherein each of the plurality of support parts is configured to rotate around an axis parallel to the second direction when a corresponding rotation pin rotates around the axis parallel to the second direction.

6. The substrate loading unit of claim 1, wherein each of the plurality of support parts have a triangular prism shape, a hexahedral shape, or a cylindrical shape.

7. The substrate loading unit of claim 1, further comprising:
a lower frame disposed between the first frame and the second frame, and disposed on a lower side of the fixed parts.

8. The substrate loading unit of claim 1, wherein the fixed parts further comprise:
second support bars extending in the first direction, and disposed on a lower side of the first support bars, and
another plurality of support parts disposed on side surfaces of the second support bars, the side surfaces facing each other.

9. A method of manufacturing a display device, the method comprising:
cutting a mother substrate and providing a preliminary substrate;
loading the preliminary substrate on a first substrate loading unit and etching the preliminary substrate;
after the etching of the preliminary substrate, loading the preliminary substrate on a second substrate loading unit and strengthening the preliminary substrate;
after the strengthening of the preliminary substrate, loading the preliminary substrate on a third substrate loading unit and etching the preliminary substrate; and
combining a substrate manufactured through the etching to a display module,
wherein each of the first substrate loading unit, the second substrate loading unit, and the third substrate loading unit comprises:
a plurality of first support bars extending in a first direction, and disposed on opposite sides of the preliminary substrate, which are opposite to each other in a second direction crossing the first direction; and
a plurality of support parts disposed on side surfaces of the first support bars, which are defined as surfaces that face each other, and
wherein the plurality of support parts are configured to rotate about a rotation axis being parallel to the second direction.

10. The method of claim 9, wherein a state, in which the plurality of support parts extend in a third direction crossing a plane defined by the first direction and the second direction, is defined as a first state, and a state, in which the plurality of support parts extend in the first direction, is defined as a second state, and
wherein a distance between support parts adjacent to each other in the first direction among the plurality of support parts varies when the plurality of support parts is changed from the first state to the second state.

11. The method of claim 10, wherein a length of each of the plurality of support parts in the first direction in the first state is smaller than a length of each of the plurality of support parts in the first direction in the second state.

12. The method of claim 10, wherein the distance between the support parts being adjacent to each other in the first direction in the first state is greater than the distance between the support parts being adjacent to each other in the first direction in the second state.

13. The method of claim 10, wherein each of the plurality of support parts in the first state have a triangular prism shape, a hexahedral shape, or a cylindrical shape.

14. The method of claim 10, wherein the loading of the preliminary substrate on the first substrate loading unit includes:
disposing the preliminary substrate between the support parts adjacent to each other in the first direction in the first state in the first substrate loading unit; and
loading the preliminary substrate, and changing the plurality of support parts of the first substrate loading unit from the first state to the second state,
wherein the loading of the preliminary substrate on the second substrate loading unit comprises:
disposing the preliminary substrate between the support parts adjacent to each other in the first direction in the first state in the second substrate loading unit; and
loading the preliminary substrate, and changing the plurality of support parts of the second substrate loading unit from the first state to the second state,
wherein the loading of the preliminary substrate on the third substrate loading unit comprises:
disposing the preliminary substrate between the support parts adjacent to each other in the first direction in the first state in the third substrate loading unit; and
loading the preliminary substrate, and changing the plurality of support parts of the third substrate loading unit from the first state to the second state.

15. The method of claim 10, wherein each of the first substrate loading unit, the second substrate loading unit, and the third substrate loading unit further comprises:
rotation pins passing through the first support bars and coupled to the plurality of support parts, respectively, and
wherein the plurality of support parts is changed from the first state to the second state when each of the rotation pins rotates around an axis parallel to the second direction.

16. The method of claim 9, wherein each of the first substrate loading unit, the second substrate loading unit, and the third substrate loading unit further comprises:
second support bars extending in the first direction, and disposed on a lower side of the first support bars, and
another plurality of support parts disposed on side surfaces of the second support bars, the side surfaces facing each other.

17. The method of claim 9, wherein each of the first substrate loading unit, the second substrate loading unit, and the third substrate loading unit further comprises:
a first frame;
a second frame spaced apart from the first frame in the first direction; and
a lower frame disposed between the first frame and the second frame, and disposed on a lower side of the first support bars,
wherein the first support bars and the plurality of support parts are disposed between the first frame and the second frame.

18. The method of claim 9, wherein the strengthening of the preliminary substrate comprises:
heating molten salt;
moving the second substrate loading unit from an upper side of the molten salt in a third direction crossing a plane defined by the first direction and the second direction, and immersing the second substrate loading unit in the molten salt; and
separating the second substrate loading unit from the molten salt.

19. The method of claim 9, wherein the providing of the preliminary substrate comprises:
stacking a plurality of mother substrates including the mother substrate in a third direction crossing a plane defined by the first direction and the second direction; and
cutting the mother substrates using a cutting member, and separating the preliminary substrate.

20. The method of claim 19. wherein the stacking of the mother substrates comprises:
stacking the mother substrates and adhesion layers alternately in the third direction.
